(19) United States
(12) Patent Application Publication
(10) Pub. No.: US 2011/0216616 A1
(43) Pub. Date: Sep. 8, 2011

(54) SEMICONDUCTOR MEMORY DEVICE

(76) Inventor: Tai-Young Ko, Seongnam-si (KR)

(21) Appl. No.: 13/014,522

(22) Filed: Jan. 26, 2011

(30) Foreign Application Priority Data
Mar. 4, 2010 (KR) 10-2010-0019482

(51) Int. Cl. G11C 7/06

(52) U.S. Cl. 365/207

(57) ABSTRACT

A semiconductor memory device includes a first and second memory cell array region, a first and second sense amplifier region interposed between the first and second memory cell array regions, a first column selection region interposed between the first sense amplifier region and the first memory cell array region and including a first column selection transistor connected between a first bit line and a first local data input/output (I/O) line, and a second column selection region interposed between the second sense amplifier region and the second memory cell array region and including a second column selection transistor connected between a second bit line and a second local data I/O line. A load of the second bit line is larger than a load of the first bit line and a threshold voltage of the first column selection transistor is higher than a threshold voltage of the second column selection transistor.

### CROSS-REFERENCE TO RELATED APPLICATION

This application claims priority under 35 U.S.C. §119 to Korean Patent Application No. 10-2010-0019482 filed on Mar. 4, 2010, the disclosure of which is hereby incorporated by reference in its entirety.

### BACKGROUND

1. Field

Embodiments of the inventive concept relate to a semiconductor memory device having an alternative sense amplifier structure in which at least two sense amplifiers are disposed in a space where at least two bit lines are disposed.

2. Description of Related Art

In recent years, with an increase in the integration density of semiconductor memory devices, a distance between bit lines has decreased. Thus, it becomes difficult to dispose one sense amplifier in a space where two bit lines are disposed. To resolve this difficulty, at least two sense amplifiers (e.g., two sense amplifiers) need to be disposed in a space where at least two bit lines (e.g., four bit lines) are disposed. In this case, however, the bit lines connected to the sense amplifier may have different loads, thereby degrading alternating-current (AC) characteristics. Therefore, a ways to reduce the negative effects of the different loads is desirable.

### SUMMARY

Embodiments of the inventive concept provide a semiconductor memory device capable of compensating for load mismatches of respective bit lines.

In accordance with an aspect of the inventive concept, a semiconductor memory device includes a first memory cell array region and a second memory cell array region disposed along a first direction. A first sense amplifier region and a second sense amplifier region are each interposed between the first and second memory cell array regions. A first column selection region is interposed between the first sense amplifier region and the first memory cell array region. The first column selection region includes a first column selection transistor connected between a first bit line and a first local data input/output (I/O) line. The first bit line extends from the first memory cell array region to the first sense amplifier region. A second column selection region is interposed between the second sense amplifier region and the second memory cell array region. The second column selection region includes a second column selection transistor connected between a second bit line and a second local data I/O line. The second bit line extends from the second memory cell array region to the first sense amplifier region. A load of the second bit line is larger than a load of the first bit line. The first sense amplifier region includes a first sense amplifier configured to sense and amplify signals of the first and second bit lines. A threshold voltage of the first column selection transistor is higher than a threshold voltage of the second column selection transistor.

The first sense amplifier region may include a first NMOS sense amplifier region and a first PMOS sense amplifier region. The first NMOS sense amplifier region may include a first NMOS sense amplifier configured to sense and amplify a signal of the first bit line or the second bit line. The first PMOS sense amplifier region may be interposed between the first NMOS sense amplifier region and the first column selection region. The first PMOS sense amplifier region may include a first PMOS sense amplifier configured to sense and amplify a signal of the first bit line or the second bit line.

The first column selection transistor may be disposed a first distance from the first sense amplifier region, and the second column selection transistor may be disposed a second distance from the second sense amplifier region, wherein the second distance is greater than the first distance. A channel width of the first column selection transistor may be smaller than a channel width of the second column selection transistor. A channel length of the first column selection transistor may be greater than a channel length of the second column selection transistor. The first column selection transistor may include a first electrode connected to the first bit line and a second electrode connected to the first local data I/O line. The second column selection transistor may include a third electrode connected to the second bit line and a fourth electrode connected to the second local data I/O line. Also, the first and second electrodes may be doped at a higher concentration than the third and fourth electrodes.

The second sense amplifier region may include a second NMOS sense amplifier region and a second PMOS sense amplifier region. The second NMOS sense amplifier region may include a second NMOS sense amplifier configured to sense and amplify a signal of a third bit line or a fourth bit line. The third bit line may extend from the first memory cell array region to the second NMOS sense amplifier region. The fourth bit line may extend from the second memory cell array region to the second sense amplifier region. A load of the fourth bit line is smaller than a load of the third bit line. The second PMOS sense amplifier region may include a second PMOS sense amplifier interposed between the second NMOS sense amplifier region and the second column selection region. The second PMOS sense amplifier region may sense and amplify a signal of the third bit line or the fourth bit line.

The first column selection region may further include a third column selection transistor connected between the third bit line and the first local data I/O line. The second column selection region may further include a fourth column selection transistor connected between the fourth bit line and the second local data I/O line. Also, a threshold voltage of the fourth column selection transistor is higher than a threshold voltage of the third column selection transistor.

The third column selection transistor may be disposed a first distance from the first sense amplifier region, and the fourth column selection transistor may be disposed a second distance from the second sense amplifier region, the second distance less than the first distance. Alternatively, or additionally, a channel width of the fourth column selection transistor may be smaller than a channel width of the third column selection transistor. Alternatively, a channel length of the fourth column selection transistor may be greater than a channel length of the third column selection transistor. The third column selection transistor may include a fifth electrode connected to the first bit line and a sixth electrode connected to the first local data I/O line. The fourth column selection transistor may include a seventh electrode connected to the second bit line and an eighth electrode connected to the second local data I/O line. Also, the seventh and eighth electrodes may be doped at a higher concentration than the fifth and sixth electrodes.

In accordance with another aspect of the inventive concept, a semiconductor memory device includes a first memory cell array region and a second memory cell array region disposed along a first direction. A first sense amplifier region is interposed between the first and second memory cell array regions. The first sense amplifier region senses and amplifies signals of a first bit line and a second bit line. The first bit line is extended from the first memory cell array region in the first direction, and the second bit line is extended from the second memory cell array region in the first direction. A load of the second bit line is larger than a load of the first bit line. A second sense amplifier region is interposed between the first sense amplifier region and the second memory cell array regions. The second sense amplifier region senses and amplifies signals of a third bit line and a fourth bit line. The third bit line is extended from the first memory cell array region in the first direction and the fourth bit line is extended from the second memory cell array region in the first direction. A load of the fourth bit line is smaller than a load of the third bit line. A first column selection transistor is connected between the first bit line and a first local data I/O line. A second column selection transistor is connected between the second bit line and a second local data I/O line. A third column selection transistor is connected between the third bit line and the first local data I/O line. A fourth column selection transistor is connected between the fourth bit line and the second local data I/O line. A threshold voltage of the first column selection transistor is higher than a threshold voltage of the second column selection transistor, and a threshold voltage of the fourth column selection transistor is higher than a threshold voltage of the third column selection transistor.

The semiconductor memory device may further include a first column selection region and a second column selection region. The first column selection region may be interposed between the first memory cell array region and the first sense amplifier region. The second column selection region may be interposed between the second memory cell array region and the second sense amplifier region. The first column selection transistor may be disposed a first distance from the first sense amplifier region within the first column selection region. The third column selection transistor may be disposed a second distance from the first sense amplifier region within the first column selection region, the second distance being greater than the first distance. The second column selection transistor may be disposed a third distance from the second sense amplifier region within the second column selection region. Also, the fourth column selection transistor may be disposed a fourth distance from the second sense amplifier region within the second column selection region, the third distance greater than the fourth distance.

The first sense amplifier region may include a first NMOS sense amplifier region and a first PMOS sense amplifier region. The first NMOS sense amplifier region may include a first NMOS sense amplifier configured to sense and amplify a signal of the first bit line or the second bit line. The first PMOS sense amplifier region may be interposed between the first NMOS sense amplifier region and the first column selection region. The first PMOS sense amplifier region may include a first PMOS sense amplifier configured to sense and amplify a signal of the first bit line or the second bit line. The second sense amplifier region may include a second NMOS sense amplifier region and a second PMOS sense amplifier region. The second NMOS sense amplifier region may include a second NMOS sense amplifier configured to sense and amplify a signal of the third bit line or the fourth bit line. The second PMOS sense amplifier region may be interposed between the second NMOS sense amplifier region and the second column selection region. The second PMOS sense amplifier region may include a second PMOS sense amplifier configured to sense and amplify a signal of the third bit line or the fourth bit line.

A channel width of the first column selection transistor may be smaller than a channel width of the second column selection transistor, and a channel width of the fourth column selection transistor may be smaller than a channel width of the third column selection transistor. Alternatively, or additionally, a channel length of the first column selection transistor may be greater than a channel length of the second column selection transistor, and a channel length of the fourth column selection transistor may be greater than a channel length of the third column selection transistor. The first column selection transistor may include a first electrode connected to the first bit line and a second electrode connected to the first local data I/O line, the second column selection transistor may include a third electrode connected to the second bit line and a fourth electrode connected to the second local data I/O line, and the first and second electrodes may be doped at a higher concentration than the third and fourth electrodes. The third column selection transistor may include a fifth electrode connected to the first bit line and a sixth electrode connected to the first local data I/O line. The fourth column selection transistor may include a seventh electrode connected to the second bit line and an eighth electrode connected to the second local data I/O line. Also, the seventh and eighth electrodes may be doped at a higher concentration than the fifth and sixth electrodes.

In accordance with still another aspect of the inventive concept, a semiconductor memory device includes a first array of memory cells coupled to a plurality of aligned first sense amplifiers, and a second array of memory cells coupled to a plurality of aligned second sense amplifiers. The device further includes a first bit line connected to a first memory cell of the first array of memory cells, a second bit line connected to a second memory cell of the second array of memory cells, a first column select transistor configured to connect to the first bit line and a first local data input/output line in response to a first column select signal, and a second column select transistor configured to connect to the second bit line and a second local data input/output line in response to a second column select signal. A threshold voltage of the first column select transistor is higher than a threshold voltage of the second column select transistor.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to like parts throughout the different views. The drawings are not necessarily to scale, emphasis instead being placed upon illustrating the principles of the inventive concepts. In the drawings:

FIG. 1 is a construction diagram of an exemplary semiconductor memory device according to embodiments of the inventive concept; and

FIG. 2 shows a sense amplifier region and a column selection region of the semiconductor memory device of FIG. 1, according to exemplary embodiments of the inventive concept.

### DETAILED DESCRIPTION

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “between,” “connected to” or “coupled to” another element or layer, it can be directly between, connected or coupled to the other element or layer or intervening elements or layers may be present. In contrast, when an element is referred to as being “directly between,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

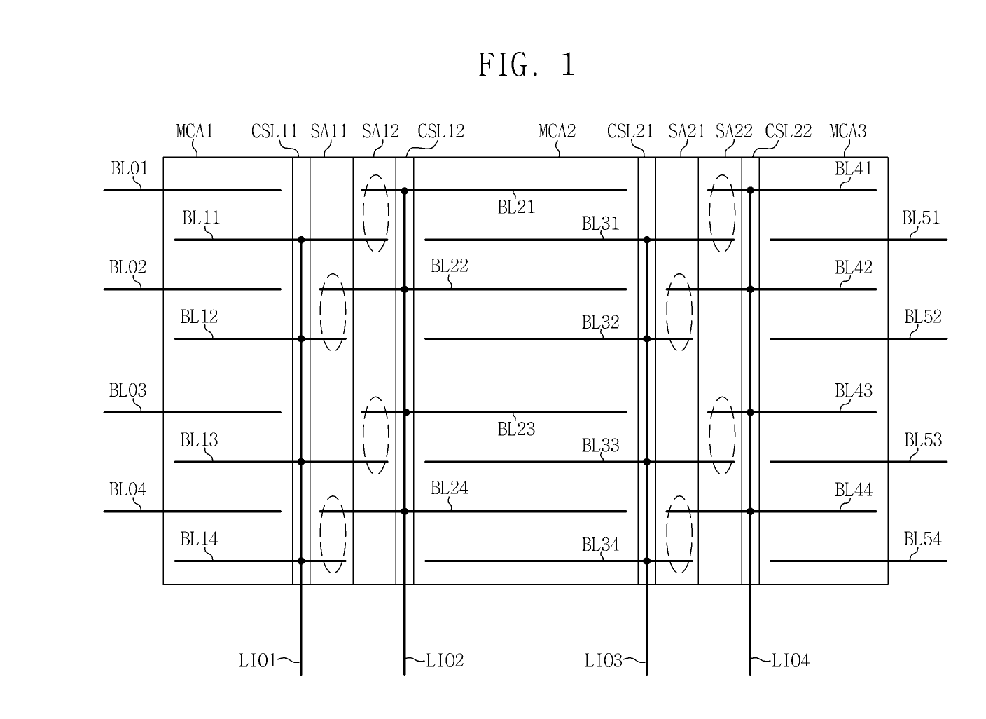

FIG. 1 is a construction diagram of an exemplary semiconductor memory device according to embodiments of the inventive concept.

Referring to FIG. 1, the semiconductor memory device may include a plurality of memory cell array regions, including MCA1, MCA2, and MCA3, a plurality of sense amplifier regions, including SA11, SA12, SA21, and SA22, and a plurality of column selection regions, including CSL11, CSL12, CSL21, and CSL22. In FIG. 1, reference numerals BL01 to BL54 denote bit lines, and reference numerals LIO1 to LIO4 denote local data I/O lines.

The memory cell array regions MCA1, MCA2, and MCA3 each include an array of memory cells, and may be disposed along a direction in which the bit lines BL01 to BL54 extend. The sense amplifier regions SA11 and SA12 may be interposed between the memory cell array regions MCA1 and MCA2, and the sense amplifier regions SA21 and SA22 may be interposed between the memory cell array regions MCA2 and MCA3. The column selection regions CSL11, CSL12, CSL21, and CSL22 may be interposed between the sense amplifier regions SA11, SA12, SA21, and SA22 and the memory cell array regions MCA1, MCA2, and MCA3, respectively.

Each of the local data I/O lines LIO1 to LIO4 may extend in a direction perpendicular to the direction in which the bit lines BL01 to BL54 extend. Similarly, the sense amplifier regions SA11, SA12, SA21, and SA22 may each include a set of sense amplifiers aligned with each other in a direction perpendicular to the direction in which the bit lines BL01 and BL54 extend.

The bit lines BL11, BL12, BL13, and BL14 may extend from the memory cell array region MCA1. In one embodiment, each bit line extends to a column selection region CSL11 and to one of two sense amplifier regions SA11 and SA12. The bit lines BL11 and BL13 may be connected to a sense amplifier disposed in the sense amplifier region SA12, and the bit lines BL12 and BL14 may be connected to a sense amplifier disposed in the sense amplifier region SA11. The bit lines BL11, BL12, BL13, and BL14 may be connected to the local data I/O line LIO1 through column selection transistors disposed in the column selection region CSL11.

The bit lines BL21, BL22, BL23, and BL24 may extend from the memory cell array region MCA2. In one embodiment, each bit line extends to a column selection region CSL1 and to one of two sense amplifier regions SA11 and SA12. The bit lines BL21 and BL23 may be connected to a sense amplifier disposed in the sense amplifier region SA12, and the bit lines BL22 and BL24 may be connected to a sense amplifier disposed in the sense amplifier region SA11. The bit lines BL21, BL22, BL23, and BL24 may be connected to the local data I/O line LIO2 through column selection transistors disposed in the column selection region CSL12.

The arrangement and connection of the bit lines BL31 to BL44 may be similar to the arrangement and connection of the bit lines BL11 to BL24. Similarly, bit lines BL01, BL02, BL03, and BL04, as well as bit lines BL51, BL52, BL53, and BL54 may extend from a respective memory cell array region MCA1 and MCA3 to additional sense amplifier regions and column select regions (not shown).

The functions of the respective blocks shown in FIG. 1 will now be described.

Each of the memory cell array regions MCA1, MCA2, and MCA3 may include a plurality of memory cells (not shown) arranged in an array configuration and connected between word lines (not shown) and bit lines, and may store and output data.

Each of the column selection regions CSL11, CSL12, CSL21, and CSL22 may include column selection transistors (not shown) connected between bit lines and the corresponding local data I/O lines, and may communicate data between the bit lines and the local data I/O lines.

Each of the sense amplifier regions SA11, SA12, SA21, and SA22 may include a sense amplifier connected to the corresponding bit lines, and may sense and amplify a signal of the bit lines. For example, each of the sense amplifier regions SA11, SA12, SA21, and SA22 may include an NMOS sense amplifier and a PMOS sense amplifier, which may sense and amplify a voltage difference between the corresponding bit lines.

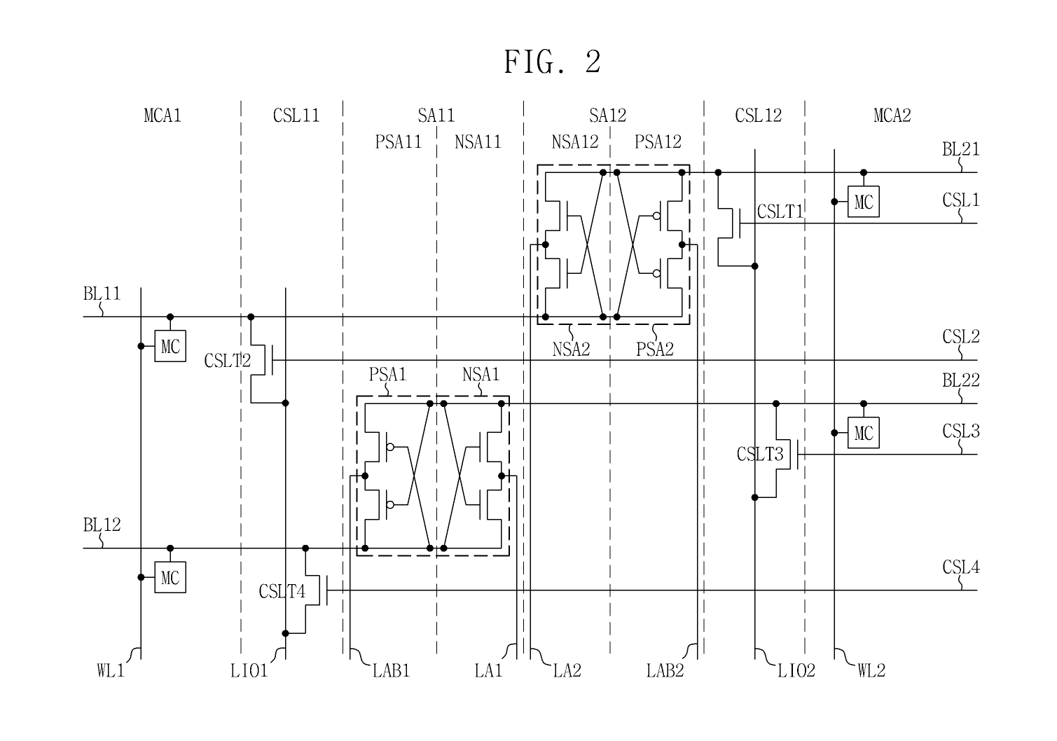

FIG. 2 is a detailed diagram of the column selection regions CSL11 and CSL12 and the sense amplifier regions SA11 and SA12 of the semiconductor memory device of FIG. 1, according to an exemplary embodiment.

The memory cell array region MCA1 may include memory cells MC connected between the word line WL1 and each of the bit lines BL11 and BL12, and the memory cell array region MCA2 may include memory cells MC connected between the word line WL2 and each of the bit lines BL21 and BL22. In one embodiment, the word lines WL1 and WL2 may be distinguished from each other by a block address. That is, the memory cell array regions MCA1 and MCA2 may be distinguished from each other by the block address, and may each include an array of memory cells addressable in certain circumstances using a single block address.

The sense amplifier region SA11 may include a sense amplifier comprised of a PMOS sense amplifier PSA1 and an NMOS sense amplifier NSA1, and may include additional sense amplifiers including PMOS and NMOS sense amplifiers (not shown) that are aligned with the PMOS and NMOS sense amplifiers PSA1 and NSA1 in a direction perpendicular to the bit lines BL12 and BL22. The sense amplifier region SA11 may include a PMOS sense amplifier region PSA11 and an NMOS sense amplifier region NSA11. Thus, the PMOS sense amplifier PSA1 may be disposed in the PMOS sense amplifier region PSA11, and the NMOS sense amplifier NSA1 may be disposed in the NMOS sense amplifier region NSA11. Also, the PMOS sense amplifier region PSA11 may be interposed between the NMOS sense amplifier region NSA11 and the column selection region CSL11. The sense amplifier region SA12 may include a PMOS sense amplifier region PSA12 and an NMOS sense amplifier region NSA12. Thus, a PMOS sense amplifier PSA2 may be disposed in the PMOS sense amplifier region PSA12, and an NMOS sense amplifier NSA2 may be disposed in the NMOS sense amplifier region NSA12. Furthermore, the PMOS sense amplifier region PSA12 may be interposed between the NMOS sense amplifier region NSA12 and the column selection region CSL12.

The column selection region CSL11 may be interposed between the memory cell array region MCA1 and the sense amplifier region SA11, and may include a column selection transistor CSLT2 connected between the bit line BL11 and the local data I/O line LIO1 and a column selection transistor CSLT4 connected between the bit line BL12 and the local data I/O line LIO1. The column selection region CSL12 may be interposed between the memory cell array region MCA2 and the sense amplifier region SA12, and may include a column selection transistor CSLT1 connected between the bit line BL21 and the local data I/O line LIO2 and a column selection transistor CSLT3 connected between the bit line BL22 and the local data I/O line LIO2.

The functions of the respective blocks shown in FIG. 2 will now be described.

In one embodiment, the functions of the respective regions MCA1, MCA2, SA11, SA12, CSL11, and CSL12 shown in FIG. 2 are the same as described with reference to FIG. 1.

The PMOS sense amplifier PSA1 may sense and amplify high-level data of the bit line BL22 configured to extend from the memory cell array region MCA2 or high-level data of the bit line BL12 configured to extend from the memory cell array region MCA1 in response to a PMOS sense amplifier drive signal LAB1. The NMOS sense amplifier NSA1 may sense and amplify low-level data of the bit line BL22 configured to extend from the memory cell array region MCA2 or low-level data of the bit line BL12 configured to extend from the memory cell array region MCA1 in response to an NMOS sense amplifier drive signal LA1.

The PMOS sense amplifier PSA2 may sense and amplify high-level data of the bit line BL21 configured to extend from the memory cell array region MCA2 or high-level data of the bit line BL11 configured to extend from the memory cell array region MCA1 in response to a PMOS sense amplifier drive signal LAB2. The NMOS sense amplifier NSA2 may sense and amplify low-level data of the bit line BL21 configured to extend from the memory cell array region MCA2 or low-level data of the bit line BL11 configured to extend from the memory cell array region MCA1 in response to an NMOS sense amplifier drive signal LA2.

The column selection transistor CSLT1 may communicate data between the bit line BL21 and the local data I/O line LIO2 in response to a column selection signal CSL1. The column selection transistor CSLT2 may communicate data between the bit line BL11 and the local data I/O line LIO1 in response to a column selection signal CSL2. The column selection transistor CSLT3 may communicate data between the bit line BL22 and the local data I/O line LIO2 in response to a column selection signal CSL3. The column selection transistor CSLT4 may communicate data between the bit line BL12 and the local data I/O line LIO1 in response to a column selection signal CSL4.

The column selection signals CSL1 to CSL4 may be selected in response to a column address, and may be enabled separately or in groups. For example, a group of column selection signals (CSL1 and CSL2, or CSL3 and CSL4) related to one sense amplifier may be enabled simultaneously.

The column selection transistor CSLT1 may have a higher threshold voltage than the column selection transistor CSLT2, and the column selection transistor CSLT4 may have a higher threshold voltage than the column selection transistor CSLT3.

The bit line BL21 configured to extend from the memory cell array region MCA2 and the bit line BL11 configured to extend from the memory cell array region MCA1 may be respectively connected to the sense amplifiers NSA2 and PSA2 of the sense amplifier region SA12. Also, the bit line BL22 configured to extend from the memory cell array region MCA2 and the bit line BL12 configured to extend from the memory cell array region MCA1 may be respectively connected to the sense amplifiers NSA1 and PSA1 of the sense amplifier region SA11. However, the bit lines BL21 and BL12 disposed respectively between the memory cell array regions MCA2 and MCA1 and the sense amplifier regions SA12 and SA11 may be shorter in length than the bit lines BL11 and BL22 disposed respectively between the memory cell array regions MCA1 and MCA2 and the sense amplifier regions SA12 and SA11 (e.g., bit lines BL12 and BL21 may each extend through respective column select regions CSL11 and CSL12 and only through one of respective sense amplifier regions SA11 and SA12, while bit lines BL11 and BL22 each extend through respective column select regions CSL11 and CSL12 and through both sense amplifier regions SA11 and SA12). As a result, the bit lines BL21 and BL12 may have smaller loads than the bit lines BL11 and BL22. Thus, the bit lines BL21 and BL12 may be more vulnerable to disturbance caused by the local data I/O lines LIO1 and LIO2 than the bit lines BL11 and BL22. To solve the foregoing problems caused by load mismatch, the column selection transistors CSLT1 and CSLT4 connected to the bit lines BL21 and BL12 may be designed to have a higher threshold voltage, while the column selection transistors CSLT2 and CSLT3 connected to the bit lines BL11 and BL22 may be designed to have a lower threshold voltage.

For example, the column selection transistors CSLT1 and CSLT4 may be disposed close to a PMOS sense amplifier region PSA of a sense amplifier region (e.g., nearby the PMOS region, and closer to the PMOS region than the NMOS region), while the column selection transistors CSLT2 and CSLT3 may be disposed far from the PMOS sense amplifier region PSA of the sense amplifier region (e.g., further than the column select transistors CSLT1 and CSLT4 are to the respective PMOS sense amplifier regions PSA, and/or further from the PMOS sense amplifier region than the NMOS sense amplifier region of the sense amplifier to which they are connected). In this case, threshold voltages of the column selection transistors CSLT1 and CSLT4 may become higher than threshold voltages of the column selection transistors CSLT2 and CSLT3 due to a well proximity effect.

Threshold voltages of column selection transistors may be adjusted in various ways. For example, source and drain electrodes of the column selection transistors CSLT1 and CSLT4 may be designed to have a higher dopant concentration than source and drain electrodes of the column selection transistors CSLT2 and CSLT3 so that the column selection transistors CSLT1 and CSLT4 can have a higher threshold voltage than the column selection transistors CSLT2 and CSLT3. Alternatively, the column selection transistors CSLT1 and CSLT4 may be adjusted to a smaller channel width or a greater channel length than the column selection transistors CSLT2 and CSLT3 so that the column selection transistors CSLT1 and CSLT4 can have a higher threshold voltage than the column selection transistors CSLT2 and CSLT3. In another case, substrate bias voltages applied to the respective column selection transistors CSLT1 to CSLT4 may be controlled to adjust the threshold voltages of the column selection transistors CSLT1 to CSLT4. For example, higher substrate bias voltages may be applied to the column selection transistors CSLT1 and CSLT4 than substrate bias voltages applied to the column selection transistors CSLT2 and CSLT3 so that the column selection transistors CSLT1 and CSLT4 can have a higher threshold voltage than the column selection transistors CSLT2 and CSLT3.

In one embodiment, only one of the above-described methods of adjusting the threshold voltages of the column selection transistors CSLT1 to CSLT4 is employed. However, in other embodiment, a combination of the above-described methods thereof may be employed.

The memory configuration described herein may be used in different types of memory device that employ memory cell arrays and sense amplifiers. For example, it may be used for DRAM, SRAM, or PRAM memory, for NAND or NOR flash memory, or for other semiconductor memory types. Furthermore, although the embodiments of the inventive concept describe the semiconductor memory device including the two sense amplifier regions interposed between the memory cell array regions, at least three sense amplifier regions may be disposed between the memory cell array regions.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A semiconductor memory device comprising:
a first memory cell array region and a second memory cell array region disposed along a first direction;
a first sense amplifier region and a second sense amplifier region, each interposed between the first and second memory cell array regions;
a first column selection region interposed between the first sense amplifier region and the first memory cell array region, the first column selection region including a first column selection transistor connected between a first bit line and a first local data input/output (I/O) line, the first bit line extending from the first memory cell array region to the first sense amplifier region; and
a second column selection region interposed between the second sense amplifier region and the second memory cell array region, the second column selection region including a second column selection transistor connected between a second bit line and a second local data I/O line, the second bit line extending from the second memory cell array region to the first sense amplifier region, wherein a load of the second bit line is larger than a load of the first bit line,
wherein the first sense amplifier region includes a first sense amplifier configured to sense and amplify signals of the first and second bit lines, and a threshold voltage of the first column selection transistor is higher than a threshold voltage of the second column selection transistor.

2. The device of claim 1, wherein the first sense amplifier region comprises:
a first NMOS sense amplifier region including a first NMOS sense amplifier configured to sense and amplify a signal of the first bit line or the second bit line; and
a first PMOS sense amplifier region interposed between the first NMOS sense amplifier region and the first column selection region, the first PMOS sense amplifier region including a first PMOS sense amplifier configured to sense and amplify a signal of the first bit line or the second bit line.

3. The device of claim 1, wherein the first column selection transistor is disposed a first distance from the first sense amplifier region, and the second column selection transistor is disposed a second distance from the first sense amplifier region, wherein the second distance is greater than the first distance.

4. The device of claim 1, wherein a channel width of the first column selection transistor is smaller than a channel width of the second column selection transistor, and/or a channel length of the first column selection transistor is greater than a channel length of the second column selection transistor.

5. The device of claim 1, further comprising:
one or more additional sense amplifiers are disposed in the first sense amplifier region and are aligned with the first sense amplifier in a direction perpendicular to the first direction.

6. The device of claim 1, wherein the first column selection transistor includes a first electrode connected to the first bit line and a second electrode connected to the first local data I/O line, the second column selection transistor includes a third electrode connected to the second bit line and a fourth electrode connected to the second local data I/O line, and the first and second electrodes are doped at a higher concentration than the third and fourth electrodes.

7. The device of claim 1, wherein the second sense amplifier region comprises:
a second NMOS sense amplifier region including a second NMOS sense amplifier configured to sense and amplify a signal of a third bit line or a fourth bit line, the third bit line extending from the first memory cell array region to the second sense amplifier region, and the fourth bit line extending from the second memory cell array region to the second sense amplifier region, wherein a load of the fourth bit line is smaller than a load of the third bit line; and
a second PMOS sense amplifier region including a second PMOS sense amplifier interposed between the second NMOS sense amplifier region and the second column selection region and configured to sense and amplify a signal of the third bit line or the fourth bit line.

8. The device of claim 7, wherein the first column selection region further includes a third column selection transistor connected between the third bit line and the first local data I/O line, the second column selection region further includes a fourth column selection transistor connected between the fourth bit line and the second local data I/O line, and a threshold voltage of the fourth column selection transistor is higher than a threshold voltage of the third column selection transistor.

9. The device of claim 8, wherein the third column selection transistor is disposed a first distance from the second sense amplifier region, and the fourth column selection transistor is disposed a second distance from the second sense amplifier region, wherein the second distance is less than the first distance.

10. The device of claim 8, wherein a channel width of the fourth column selection transistor is smaller than a channel width of the third column selection transistor, and/or a channel length of the fourth column selection transistor is greater than a channel length of the third column selection transistor.

11. The device of claim 8, wherein one or more additional sense amplifiers are disposed in the second sense amplifier region and are aligned with the second sense amplifier in a direction perpendicular to the first direction.

12. The device of claim 8, wherein the third column selection transistor includes a fifth electrode connected to the first bit line and a sixth electrode connected to the first local data I/O line, the fourth column selection transistor includes a seventh electrode connected to the second bit line and an eighth electrode connected to the second local data I/O line, and the seventh and eighth electrodes are doped at a higher concentration than the fifth and sixth electrodes.

13. A semiconductor memory device comprising:
a first memory cell array region and a second memory cell array region disposed along a first direction;
a first sense amplifier region interposed between the first and second memory cell array regions, the first sense amplifier region being configured to sense and amplify a signal of a first bit line and a signal of a second bit line, the first bit line extending from the first memory cell array region in the first direction, the second bit line extending from the second memory cell array region in the first direction, wherein a load of the second bit line is larger than a load of the first bit line;
a second sense amplifier region interposed between the first sense amplifier region and the second memory cell array regions, the second sense amplifier region being configured to sense and amplify a signal of a third bit line and a signal of a fourth bit line, the third bit line extending from the first memory cell array region in the first direction, the fourth bit line extending from the second memory cell array region in the first direction, wherein a load of the fourth bit line is smaller than a load of the third bit line;
a first column selection transistor connected between the first bit line and a first local data I/O line;
a second column selection transistor connected between the second bit line and a second local data I/O line;
a third column selection transistor connected between the third bit line and the first local data I/O line; and
a fourth column selection transistor connected between the fourth bit line and the second local data I/O line,
wherein a threshold voltage of the first column selection transistor is higher than a threshold voltage of the second column selection transistor, and a threshold voltage of the fourth column selection transistor is higher than a threshold voltage of the third column selection transistor.

14. The device of claim 13, further comprising:
a first column selection region interposed between the first memory cell array region and the first sense amplifier region; and
a second column selection region interposed between the second memory cell array region and the second sense amplifier region,
wherein the first column selection transistor is disposed a first distance from the first sense amplifier region within the first column selection region, the third column selection transistor is disposed a second distance from the first sense amplifier region within the first column selection region, the first distance being less than the second distance, the second column selection transistor is disposed a third distance from the second sense amplifier region within the second column selection region, and the fourth column selection transistor is disposed a fourth distance from the second sense amplifier region within the second column selection region, the third distance being greater than the fourth distance.

15. The device of claim 14, wherein the first sense amplifier region comprises:
a first NMOS sense amplifier region including a first NMOS sense amplifier configured to sense and amplify a signal of the first bit line or the second bit line; and
a first PMOS sense amplifier region interposed between the first NMOS sense amplifier region and the first column selection region, the first PMOS sense amplifier region including a first PMOS sense amplifier configured to sense and amplify a signal of the first bit line or the second bit line.

16. The device of claim 15, wherein the second sense amplifier region comprises:
a second NMOS sense amplifier region including a second NMOS sense amplifier configured to sense and amplify a signal of the third bit line or the fourth bit line; and
a second PMOS sense amplifier region interposed between the second NMOS sense amplifier region and the second column selection region, the second PMOS sense amplifier region including a second PMOS sense amplifier configured to sense and amplify a signal of the third bit line or the fourth bit line.

17. The device of claim 16, wherein one or more additional sense amplifiers are disposed each of the first NMOS amplifier region, the first PMOS amplifier region, the second NMOS amplifier region, and the second PMOS amplifier region, and are respectively aligned, in a direction perpendicular to the first direction, with the respective first NMOS sense amplifier, first PMOS sense amplifier, second NMOS sense amplifier, and second PMOS sense amplifier.

18. The device of claim 13, wherein a channel width of the first column selection transistor is smaller than a channel width of the second column selection transistor, and/or a channel length of the first column selection transistor is greater than a channel length of the second column selection transistor; and a channel width of the fourth column selection transistor is smaller than a channel width of the third column selection transistor, and/or a channel length of the fourth column selection transistor is greater than a channel length of the third column selection transistor.

19. The device of claim 13, wherein the first column selection transistor includes a first electrode connected to the first bit line and a second electrode connected to the first local data I/O line, the second column selection transistor includes a third electrode connected to the second bit line and a fourth electrode connected to the second local data I/O line, and the first and second electrodes are doped at a higher concentration than the third and fourth electrodes, and
the third column selection transistor includes a fifth electrode connected to the first bit line and a sixth electrode connected to the first local data I/O line, the fourth column selection transistor includes a seventh electrode connected to the second bit line and an eighth electrode connected to the second local data I/O line, and the seventh and eighth electrodes are doped at a higher concentration than the fifth and sixth electrodes.

20. A semiconductor memory device comprising:
a first array of memory cells coupled to a plurality of aligned first sense amplifiers;
a second array of memory cells coupled to a plurality of aligned second sense amplifiers;
a first bit line connected to a first memory cell of the first array of memory cells;
a second bit line connected to a second memory cell of the second array of memory cells;
a first column select transistor configured to connect to the first bit line and a first local data input/output line in response to a first column select signal; and
a second column select transistor configured to connect to the second bit line and a second local data input/output line in response to a second column select signal,
wherein a threshold voltage of the first column select transistor is higher than a threshold voltage of the second column select transistor.
